(19) United States
(12) Patent Application Publication
(10) Pub. No.: US 2023/0187225 A1
(43) Pub. Date: Jun. 15, 2023

(54) METHOD FOR MANUFACTURING SEMICONDUCTOR DEVICE

(71) Applicant: Mitsubishi Electric Corporation, Tokyo (JP)

(72) Inventors: Naoki YOSHIMATSU, Tokyo (JP); Takaaki SHIRASAWA, Tokyo (JP)

(73) Assignee: Mitsubishi Electric Corporation, Tokyo (JP)

(21) Appl. No.: 17/996,604

(22) PCT Filed: Jul. 14, 2020
(86) PCT No.: PCT/JP2020/027338

§ 371 Date: Oct. 19, 2022

(51) Int. Cl. H01L 21/56; H01L 21/48; H01L 23/40

(52) U.S. Cl. CPC H01L 21/565; H01L 21/4821; H01L 21/561; H01L 23/4006; H01L 2023/4087

(57) ABSTRACT

A method for manufacturing a semiconductor device includes steps (a) to (e). In the step (a), a lead frame including a plurality of lead portions, tie bars, a frame body, and ring portions is prepared. In the step (b), an assembled body is formed. In the step (c), the assembled body is placed in a cavity. In the step (d), a molding resin in a liquid form is injected into the cavity and cured in a state in which a pin is inserted through a hole of the ring portion and an upper surface of the ring portion is in contact with an inner surface of the upper die, and a resin-molded body is formed. In the step (e), the frame body, the tie bars, and connecting portions are cut after the resin-molded body is taken out from the molding die.

### TECHNICAL FIELD

The present disclosure relates to a method for manufacturing a semiconductor device.

### BACKGROUND ART

Conventionally, in fixing a semiconductor device to a cooler that is a member in which the semiconductor device is mounted, a screw is inserted through a mounting hole of a molding resin, and the semiconductor device is directly fastened with the screw. Due to slight unevenness or slight inclination of an upper surface of the molding resin, a bearing surface of the screw comes into contact with the molding resin such that partial contact is made therebetween. Onto the molding resin in such a state, an axial force during screwing and a stress amplitude due to a temperature change after the fastening are applied. Then, a creep phenomenon occurs in which the molding resin is deformed from a portion thereof applied with higher stress, so that the axial force after the fastening decreases.

In order to prevent this phenomenon, there is formed a structure in which a collar formed by cutting or forging is inserted into the mounting hole of the molding resin and fastening is performed with a screw via the collar. In this structure, the collar receives an axial force of the screw and the load is directly transmitted to the member in which the device is mounted, whereby a creep phenomenon can be prevented. However, because of addition of the collar and addition of the inserting process, there is caused a problem of increased cost for manufacturing a semiconductor device.

Then, Patent Document 1, for example, discloses a structure in which a part of a lead frame is bent to fasten an exposed portion of an upper surface exposed in an upper surface of a molding resin with a screw, and the exposed portion of the upper surface is connected to an exposed portion of a lower surface exposed in a lower surface of the molding resin by a load support portion inside the molding resin. In this structure, a collar is not added, but a part of the lead frame is used. This can reduce an increase in cost for manufacturing a semiconductor device due to addition of a collar.

### PRIOR ART DOCUMENT

### Patent Document

Patent Document 1: Japanese Patent Application Laid-Open No. 2014-183242

### SUMMARY

### Problem to be Solved by the Invention

However, according to the technique described in Patent Document 1, in order to expose the exposed portion of the upper surface and the exposed portion of the lower surface of the lead frame in the upper surface and the lower surface of the molding resin, respectively, a dimension between an upper die and a lower die forming a die in contact with the exposed portions of the upper surface and the lower surface of the lead frame during resin molding needs to be equal to a dimension between the exposed portions of the upper surface and the lower surface.

In a case in which the dimension between the upper die and the lower die is larger than the dimension between the exposed portions of the upper surface and the lower surface, a resin burr is generated in a portion that should be exposed. On the other hand, in a case in which the dimension between the exposed portions of the upper surface and the lower surface is larger than the dimension between the upper die and the lower die, the die may compress the lead frame during molding, which produces residual stress, causing a concern about a resin crack after molding. Thus, there arises a problem of increased cost for manufacturing the lead frame and the die to improve the dimensional accuracy of those components.

In view of this, it is an object of the present disclosure to provide a technique that can prevent occurrence of a creep phenomenon in screwing a semiconductor device to a member in which the semiconductor device is mounted, and also can reduce an increase in cost for manufacturing a semiconductor device.

### Means to Solve the Problem

A method for manufacturing a semiconductor device according to the present disclosure includes the steps of: (a) preparing a lead frame including a plurality of lead portions, a tie bar that connects intermediate portions of the plurality of lead portions and extends along an arrangement direction of the plurality of lead portions, a frame body that connects both end portions of the plurality of lead portions and the tie bar and is placed so as to surround the plurality of lead portions and the tie bar, and a ring portion placed on an inner-surface side of the frame body via a connecting portion; (b) connecting a semiconductor element to the lead frame to form an assembled body; (c) placing the assembled body in a cavity of a molding die including an upper die and a lower die; (d) injecting a molding resin in a liquid form into the cavity and curing the molding resin in a state in which a pin provided in the lower die is inserted through a hole of the ring portion and an upper surface of the ring portion is in contact with an inner surface of the upper die, to form a resin-molded body; and (e) cutting the frame body, the tie bar, and the connecting portion after taking out the resin-molded body from the molding die.

### Effects of the Invention

According to the present disclosure, curing is performed in a state in which the lower surface of the ring portion is in contact with the molding resin in a liquid form in the cavity of the molding die. Thus, no gap is formed between the lower surface of the ring portion and the molding resin, and the lower surface of the ring portion and the molding resin are in contact with each other at all portions. Therefore, when the semiconductor device is screwed to the member in which the semiconductor device is mounted, while the bearing surface of the screw presses the ring portion, the ring portion presses the molding resin in close contact with the lower surface of the ring portion. As a result, neither partial contact nor point contact occurs, and uniform pressing is obtained. Consequently, occurrence of a creep phenomenon can be prevented.

Further, the ring portion, when provided as a component, is a part of the lead frame, and hence cost for components and processes can be reduced, whereby an increase in cost for manufacturing a semiconductor device can be reduced.

Objects, features, aspects, and advantages of this disclosure will become more apparent from the following detailed description and the accompanying drawings.

### BRIEF DESCRIPTION OF DRAWINGS

FIG. 1 is a plan view of a resin-molded body taken out from a molding die after resin molding according to a first embodiment.

FIG. 2 is a front view of the resin-molded body taken out from the molding die after resin molding.

FIG. 3 is a plan view of a semiconductor device formed after tie bars, a frame body, and connecting portions are cut.

FIG. 4 is a sectional view for explaining placement of an assembled body in a cavity of the molding die in a method for manufacturing a semiconductor device according to the first embodiment.

FIG. 5 is a sectional view for explaining injection of the molding resin in a liquid form into the cavity of the molding die in the method for manufacturing a semiconductor device according to the first embodiment.

FIG. 6 is a sectional view for explaining taking-out of the resin-molded body from the molding die in the method for manufacturing a semiconductor device according to the first embodiment.

FIG. 7 is a sectional view for explaining cutting of the frame body, the tie bars, and the connecting portions from the resin-molded body in the method for manufacturing a semiconductor device according to the first embodiment.

FIG. 8 is an enlarged sectional view of a portion of the semiconductor device that is screwed to a cooler.

FIG. 9 is an enlarged sectional view of a periphery of a ring portion of a resin-molded body according to a second embodiment.

FIG. 10 is an enlarged sectional view of a periphery of a ring portion of a resin-molded body according to a third embodiment.

FIG. 11 is an enlarged sectional view of a periphery of a ring portion of a resin-molded body according to a fourth embodiment.

FIG. 12 is an enlarged sectional view of a periphery of a ring portion of a resin-molded body according to a fifth embodiment.

FIG. 13 is an enlarged sectional view of a periphery of a ring portion in a state in which an assembled body is placed in a cavity of a molding die according to a fifth embodiment.

FIG. 14 is an enlarged sectional view of a periphery of a ring portion of a resin-molded body according to a sixth embodiment.

### DESCRIPTION OF EMBODIMENTS

### First Embodiment

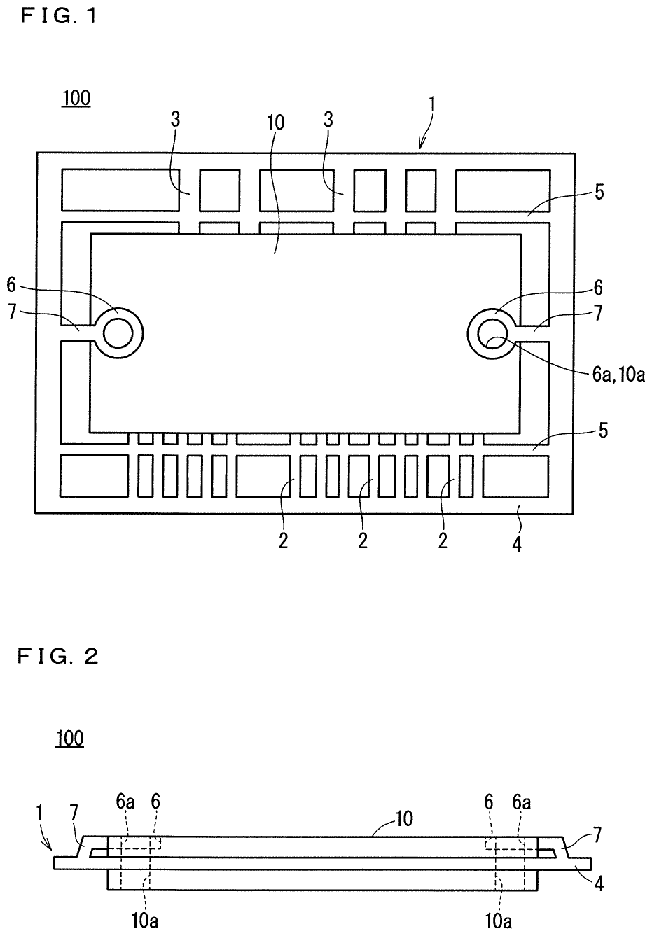

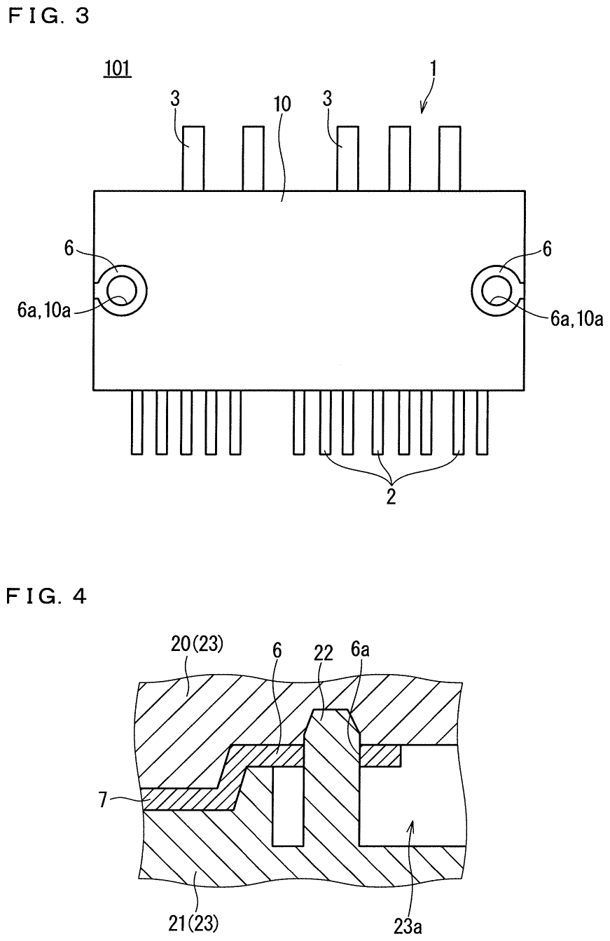

A first embodiment will be described below with reference to the drawings. FIG. 1 is a plan view of a resin-molded body 100 taken out from a molding die after resin molding according to a first embodiment. FIG. 2 is a front view of the resin-molded body 100 taken out from the molding die after resin molding. FIG. 3 is a plan view of a semiconductor device 101 formed after tie bars 5, a frame body 4, and connecting portions 7 are cut.

As shown in FIGS. 1 and 2, the resin-molded body 100 includes a molding resin 10 and a lead frame 1.

As the molding resin 10, for example, an epoxy resin is used. In the molding resin 10, a semiconductor element is die-bonded onto a die pad (not shown) of the lead frame 1, and is electrically connected to lead portions 2 and 3 of the lead frame 1 by an aluminum wire or the like.

The lead frame 1 is formed using metal such as copper, for example, and includes the die pad, a plurality of lead portions 2 and 3, two tie bars 5, a frame body 4, two ring portions 6, and two connecting portions 7.

The plurality of lead portions 2 and 3 extend from forward and backward side surfaces of the molding resin 10 in forward and backward directions, respectively, and are arranged along a lateral direction in FIG. 1. The plurality of lead portions 2 are signal terminals, and the plurality of lead portions 3 are main terminals.

The two tie bars 5 connect intermediate portions of the plurality of lead portions 2 and 3 in the forward and backward directions of the molding resin 10, respectively, and extend along an arrangement direction of the plurality of lead portions 2 and 3. The frame body 4 connects both end portions of the plurality of lead portions 2 and 3 and the two tie bars 5 and is placed so as to surround the plurality of lead portions 2 and 3 and the two tie bars 5.

The ring portions 6 are placed on the inner-surface side of the frame body 4 via the connecting portions 7. More specifically, the two ring portions 6 are embedded such that the upper surfaces thereof are exposed at right and left end portions of the molding resin 10 in FIG. 1. At the right and left end portions of the molding resin 10, two mounting holes 10a each in a form of a through hole for fixing to a cooler that is a member in which a device is mounted, using screws, are formed, respectively, and holes 6a of the two ring portions 6 communicate with the two mounting holes 10a, respectively. Intermediate portions of the connecting portions 7 are bent upward. Thus, the ring portions 6 are positioned above the frame body 4.

As shown in FIG. 3, when the tie bars 5, the frame body 4, and the connecting portions 7 are cut from the resin-molded body 100 by pressing, the semiconductor device 101 is completed.

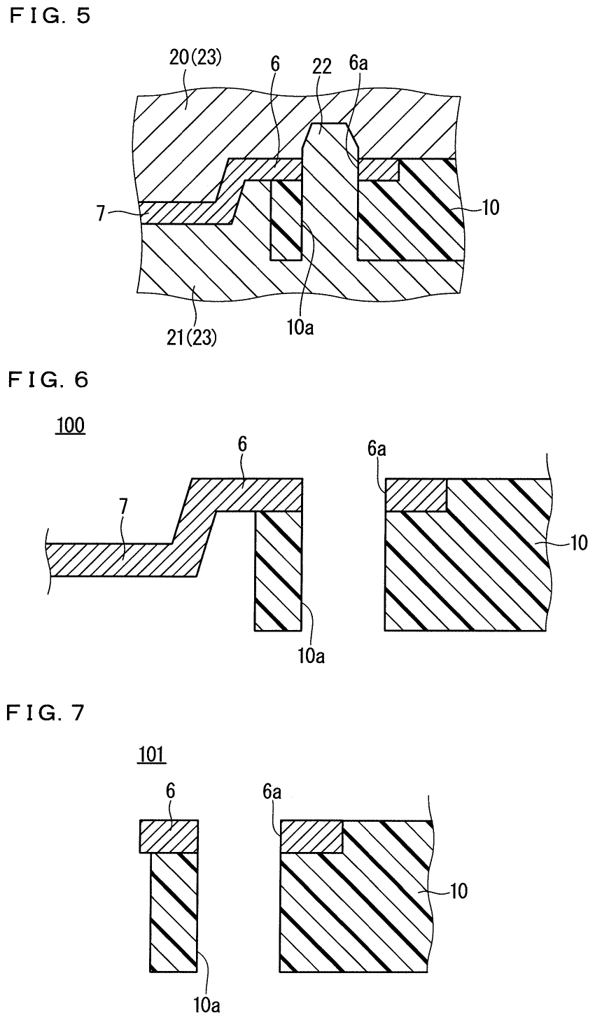

Next, a method for manufacturing the semiconductor device 101 will be described with reference to FIGS. 4 to 7. FIG. 4 is a sectional view for explaining placement of an assembled body in a cavity 23a of a molding die 23 in the method for manufacturing a semiconductor device. FIG. 5 is a sectional view for explaining injection of the molding resin 10 in a liquid form into the cavity 23a of the molding die 23 in the method for manufacturing a semiconductor device. FIG. 6 is a sectional view for explaining taking-out of the resin-molded body 100 from the molding die 23 in the method for manufacturing a semiconductor device. FIG. 7 is a sectional view for explaining cutting of the frame body 4, the tie bars 5, and the connecting portions 7 from the resin-molded body 100 in the method for manufacturing a semiconductor device.

First, the lead frame 1 including the plurality of lead portions 2 and 3, the tie bars 5, the frame body 4, and the ring portions 6 is prepared. Secondly, the semiconductor element is die-bonded onto the die pad of the lead frame 1, and then connected to the lead portions 2 and 3 with an aluminum wire or the like. Thus, an assembled body is formed.

Subsequently, as shown in FIG. 4, the assembled body is placed in the cavity 23a that is a space in the molding die 23 including an upper die 20 and a lower die 21.

At that time, the hole 6a of the ring portion 6 in the assembled body is inserted through a pin 22 provided in the lower die 21. Note that the pin 22 is preferably a fixed pin, but may be a movable pin. As shown in FIG. 5, with the upper surface of the ring portion 6 being in contact with the inner surface of the upper die 20, the molding resin 10 in a liquid form, in other words, the molten molding resin 10, is injected into the cavity 23a. In a case in which the molding resin 10 is a thermosetting epoxy resin, the molding resin 10 melted in the molding die 23 is reacted while being maintained in a high-temperature and high-pressure state, to be cured. Thus, the resin-molded body 100 (see FIG. 1) is formed.

Subsequently, the upper die 20 and the lower die 21 are opened, and the resin-molded body 100 is taken out as shown in FIG. 6. At that time, the molding resin 10 has a shape corresponding to the shape of the cavity 23a in a state in which the molding die 23 is closed.

Subsequently, the frame body 4, the tie bars 5, and the connecting portions 7 are cut from the resin-molded body 100 by pressing, and the semiconductor device 101 is manufactured as shown in FIG. 7. In addition, the lead portions 2 and 3 serving as signal terminals and main terminals may be bent into desired shapes, as necessary. The ring portions 6 are placed around the mounting holes 10a, and the upper surfaces of the ring portions 6 are exposed from the molding resin 10.

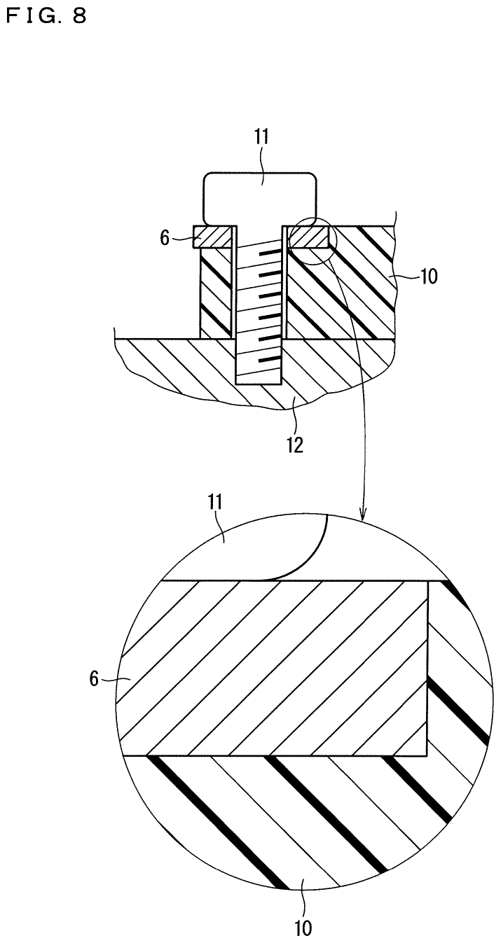

Next, with reference to FIG. 8, effects produced by the semiconductor device 101 manufactured by the above-described manufacturing method will be described in comparison with a case in which the ring portion 6 is not provided. FIG. 8 is an enlarged sectional view of a portion of the semiconductor device 101 that is screwed to a cooler 12.

In a case in which the ring portion 6 is not provided, the semiconductor device 101 is fastened with the bearing surface of a screw being in direct contact with a molding resin. The upper surface of the molding resin and the bearing surface of the screw seem to be flat, but fine unevenness is found in each of the surfaces when enlarged. The surfaces are in contact with each other at protrusions thereof. When an axial force is applied thereto, a high pressure is applied to the contact portion, and the molding resin is plastically deformed (creeps) by heat generated due to operations of the semiconductor element.

In contrast thereto, as shown in FIG. 8, in the first embodiment, regarding contact between the molding resin 10 and the ring portion 6, the lower surface of the ring portion 6 and the molding resin 10 are in contact with each other at all portions because the molten molding resin 10 is cured while being in contact with the lower surface of the ring portion 6. As a result, a pressure caused by an axial force of a metal screw 11 is uniform, and hence a creep phenomenon is unlikely to occur. Further, the bearing surface of the screw 11 is in contact with the upper surface of the ring portion 6, but both are made of metal, thereby having high resistance to a creep phenomenon.

As described above, the method for manufacturing a semiconductor device according to the first embodiment includes the steps of: (a) preparing the lead frame 1 including the plurality of lead portions 2 and 3, the tie bars 5 that connect intermediate portions of the plurality of lead portions 2 and 3 and extend along an arrangement direction of the plurality of lead portions 2 and 3, the frame body 4 that connects both end portions of the plurality of lead portions 2 and 3 and the tie bars 5 and is placed so as to surround the plurality of lead portions 2 and 3 and the tie bars 5, and the ring portions 6 placed on an inner-surface side of the frame body 4 via the connecting portions 7; (b) connecting a semiconductor element to the lead frame 1 to form an assembled body; (c) placing the assembled body in the cavity 23a of the molding die 23 including the upper die 20 and the lower die 21; (d) injecting the molding resin 10 in a liquid form into the cavity 23a and curing the molding resin 10 in a state in which the pin 22 provided in the lower die 21 is inserted through the hole 6a of the ring portion 6 and the upper surface of the ring portion 6 is in contact with the inner surface of the upper die 20, to form the resin-molded body 100; and (e) cutting the frame body 4, the tie bars 5, and the connecting portions 7 after taking out the resin-molded body 100 from the molding die 23.

The lower surface of the ring portion 6 is cured while being in contact with the molding resin 10 in a liquid form in the cavity 23a of the molding die 23. Thus, no gap is formed between the lower surface of the ring portion 6 and the molding resin 10, and the lower surface of the ring portion 6 and the molding resin 10 are in contact with each other at all portions. Therefore, when the semiconductor device 101 is screwed to the cooler 12 that is a member in which the semiconductor device 101 is mounted, while the bearing surface of the screw 11 presses the ring portion 6, the ring portion 6 presses the molding resin 10 in close contact with the lower surface of the ring portion 6. As a result, neither partial contact nor point contact occurs, and uniform pressing is obtained. Consequently, occurrence of a creep phenomenon can be prevented. For the above-described reasons, the semiconductor device 101 can be used for a long period of time.

Further, the ring portion 6, when provided as a component, is a part of the lead frame 1, and hence cost for components and processes can be reduced, whereby an increase in cost for manufacturing the semiconductor device 101 can be reduced.

Moreover, according to the technique described in Patent Document 1, when the exposed portion of the upper surface and the exposed portion of the lower surface are compressed by an axial force caused due to screwing, strain is generated in the load support portion, and a crack may probably occur around the load support portion in the molding resin.

In contrast thereto, according to the first embodiment, the lower surface of the ring portion 6 and the molding resin 10 are in contact with each other at all portions, and hence no strain is generated in the ring portion 6, and stress is uniformly applied to the molding resin 10. Therefore, generation of a crack is prevented. Further, it is not required to have such a strict dimensional accuracy as to make the upper surface and the lower surface of the lead frame 1 flush with the inner surface of the molding die 23 during placement of the assembled body in the molding die 23.

### Second Embodiment

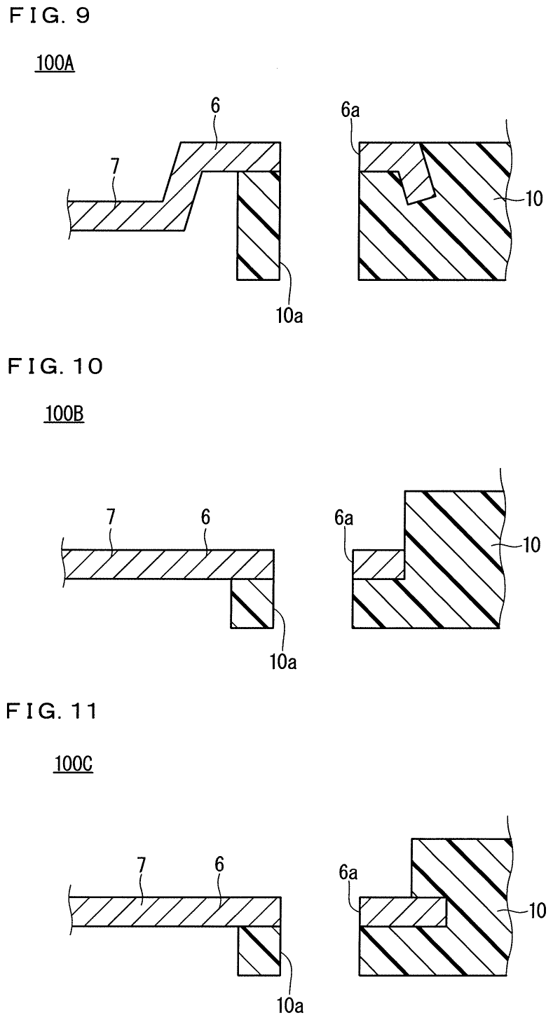

Next, a method for manufacturing a semiconductor device according to a second embodiment will be described. FIG. 9 is an enlarged sectional view of a periphery of the ring portion 6 of a resin-molded body 100A according to the second embodiment. Note that, in the second embodiment, the same components as those described in the first embodiment are denoted by the same reference signs, and description thereof is omitted.

As shown in FIG. 9, in the second embodiment, a tip end portion of the ring portion 6 located in a direction extending from the frame body 4 toward the ring portion 6 via the connecting portion 7 is bent downward so as not to be in contact with the inner surface of the upper die 20. In this state, resin molding is performed, so that the downward-bent tip end portion of the ring portion 6 is embedded in the molding resin 10. As a result, after the frame body 4 is cut, the ring portion 6 can be prevented from being detached from the molding resin 10 also in a case in which adhesion between the molding resin 10 and the ring portion 6 is weak.

### Third Embodiment

Next, a method for manufacturing a semiconductor device according to a third embodiment will be described. FIG. 10 is an enlarged sectional view of a periphery of the ring portion 6 of a resin-molded body 100B according to the third embodiment. Note that, in the third embodiment, the same components as those described in the first and second embodiments are denoted by the same reference signs, and description thereof is omitted.

As shown in FIG. 10, in the third embodiment, the connecting portion 7 and the ring portion 6 that protrude from the frame body 4 toward the inner-surface side are formed linearly in a sectional view. That is, the upper surfaces of the ring portion 6 and the connecting portion 7 are on the same level with the upper surface of the frame body 4. This eliminates a need for bending in a stage of forming the lead frame 1, thereby reducing cost for components of the lead frame 1, cost for the dies, packaging cost, and transportation cost.

### Fourth Embodiment

Next, a method for manufacturing a semiconductor device according to a fourth embodiment will be described. FIG. 11 is an enlarged sectional view of a periphery of the ring portion 6 of a resin-molded body 100C according to the fourth embodiment. Note that, in the fourth embodiment, the same components as those described in the first to third embodiments are denoted by the same reference signs, and description thereof is omitted.

In the fourth embodiment, as compared with the third embodiment, a recess that is recessed upward is formed in the inner surface of the upper die 20. Further, as shown in FIG. 11, a tip end of the ring portion 6 located in a direction extending from the frame body 4 toward the ring portion 6 via the connecting portion 7 extends to an entrance of the recess in the upper die 20 so as not to be in contact with the inner surface of the upper die 20. Here, in FIG. 11, a portion of the molding resin 10 located above the ring portion 6 is formed of the recess in the upper die 20. In other words, the above-mentioned portion corresponds to the recess of the upper die 20.

In the same manner as in the second embodiment, the tip end of the ring portion 6 is embedded in the molding resin 10. As a result, after the frame body 4 is cut, the ring portion 6 can be prevented from being detached from the molding resin 10 also in a case in which adhesion between the molding resin 10 and the ring portion 6 is weak.

### Fifth Embodiment

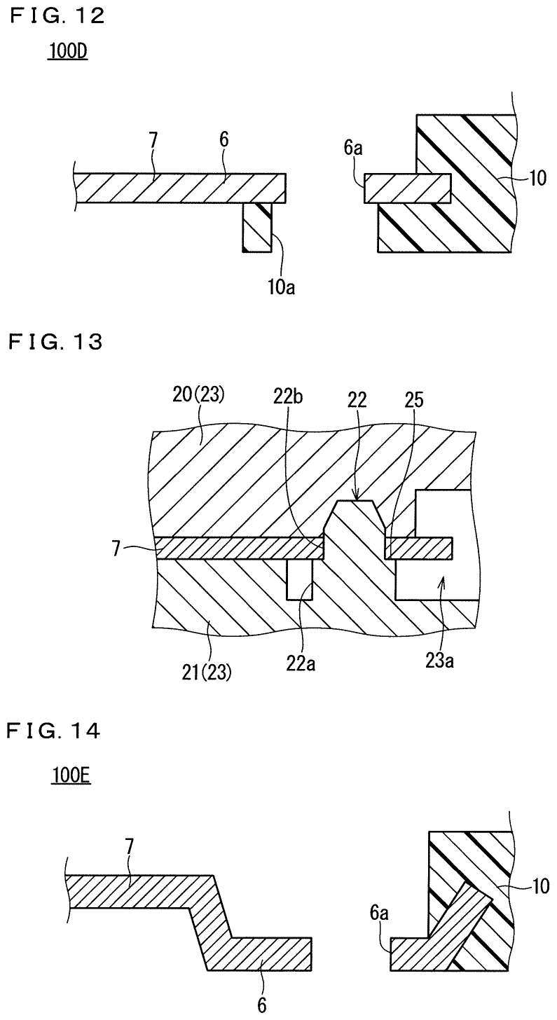

Next, a method for manufacturing a semiconductor device according to a fifth embodiment will be described. FIG. 12 is an enlarged sectional view of a periphery of the ring portion 6 of a resin-molded body 100D according to the fifth embodiment. FIG. 13 is an enlarged sectional view of a periphery of the ring portion 6 in a state in which the assembled body is placed in the cavity 23a of the molding die 23 according to the fifth embodiment. Note that, in the fifth embodiment, the same components as those described in the first to fourth embodiments are denoted by the same reference signs, and description thereof is omitted.

As shown in FIGS. 12 and 13, in the second embodiment, a stepped portion 25 is formed in the pin 22 of the lower die 21. The pin 22 includes a large-diameter portion 22a forming a lower portion and a small-diameter portion 22b forming an upper portion.

The stepped portion 25 is formed in a portion connecting the large-diameter portion 22a and the small-diameter portion 22b. The diameter of the hole 6a of the ring portion 6 is slightly larger than the diameter of the small-diameter portion 22b and smaller than the diameter of the large-diameter portion 22a. Thus, in setting the assembled body in the lower die 21, despite an attempt to insert the pin 22 through the hole 6a of the ring portion 6, the pin 22 stops advancing due to the stepped portion 25.

The lead frame 1 is made of metal but is a thin plate having been processed, and thus the lead frame 1 has no thickness-direction stiffness. In addition, during resin molding, the molding resin 10 in a liquid form flows into the cavity 23a and also enters a minute gap. Thus, in a state in which the lead frame 1 is in light contact with the upper die 20, the lead frame 1 is deformed due to warpage or deflection existing in the lead frame 1 and due to the pressure or the flow velocity of the molding resin 10, so that a gap is formed between the upper die 20 and the lead frame 1. The molding resin 10 flows into the gap to form a resin burr.

In contrast thereto, in the fifth embodiment, the ring portion 6 is sandwiched between the upper die 20 and the stepped portion 25 of the pin 22, to be fixed. Thus, injection of the molten molding resin 10 into the molding die 23 does not cause formation of a gap between the ring portion 6 and the upper die 20, so that no resin bur is formed. Note that the structure of the ring portion 6 according to the fifth embodiment can be applied to the first to fourth embodiments.

### Sixth Embodiment

Next, a method for manufacturing a semiconductor device according to a sixth embodiment will be described. FIG. 14 is an enlarged sectional view of a periphery of the ring portion 6 of a resin-molded body 100E according to the sixth embodiment. Note that, in the sixth embodiment, the same components as those described in the first to fifth embodiments are denoted by the same reference signs, and description thereof is omitted.

As shown in FIG. 14, in the sixth embodiment, a recess that is recessed upward is formed in the inner surface of the upper die 20, and an intermediate portion of the connecting portion 7 is bent downward. A tip end portion of the ring portion 6 located in a direction extending from the frame body 4 toward the ring portion 6 via the connecting portion 7 extends to an entrance of the recess so as not to be in contact with the upper die 20 and the lower die 21, and is bent upward. Here, in FIG. 14, a portion of the molding resin 10 located above the ring portion 6 is formed of the recess in the upper die 20. In other words, the above-mentioned portion corresponds to the recess of the upper die 20.

Thus, during resin molding, a lower surface of a portion other than the tip end portion in the ring portion 6 comes into contact with the inner surface of the lower die 21, and hence the molding resin 19 is not provided below the hole 6a of the ring portion 6. In other words, the molding resin 10 is not provided in a portion applied with an axial force during screwing, and hence a creep phenomenon does not occur. As a result, the screw 11 can be prevented from becoming loose.

Although this disclosure has been described in detail, the above description is illustrative and not restrictive in all aspects. It is understood that numerous modifications not described can be conceived.

Additionally, the respective embodiments can be freely combined and each of the embodiments can be appropriately modified or omitted.

### EXPLANATION OF REFERENCE SIGNS

1: lead frame
2, 3: lead portion
4: frame body
5: tie bar
6: ring portion
7: connecting portion
10: molding resin
20: upper die
21: lower die
22: pin
23: molding die
23a: cavity
25: stepped portion
100, 100A, 100B, 100C, 100D, 100E: resin-molded body
101: semiconductor device

1. A method for manufacturing a semiconductor device comprising the steps of:
(a) preparing a lead frame including a plurality of lead portions, a tie bar that connects intermediate portions of the plurality of lead portions and extends along an arrangement direction of the plurality of lead portions, a frame body that connects both end portions of the plurality of lead portions and the tie bar and is placed so as to surround the plurality of lead portions and the tie bar, and a ring portion placed on an inner-surface side of the frame body via a connecting portion;
(b) connecting a semiconductor element to the lead frame to form an assembled body;
(c) placing the assembled body in a cavity of a molding die including an upper die and a lower die;
(d) injecting a molding resin in a liquid form into the cavity and curing the molding resin in a state in which a pin provided in the lower die is inserted through a hole of the ring portion and an upper surface of the ring portion is in contact with an inner surface of the upper die, to form a resin-molded body; and
(e) cutting the frame body, the tie bar, and the connecting portion after taking out the resin-molded body from the molding die.

2. The method for manufacturing a semiconductor device according to claim 1, wherein a tip end portion of the ring portion located in a direction extending from the frame body toward the ring portion via the connecting portion is bent downward so as not to be in contact with the inner surface of the upper die.

3. The method for manufacturing a semiconductor device according to claim 1, wherein the upper surface of the ring portion and an upper surface of the connecting portion are on the same level with an upper surface of the frame body.

4. The method for manufacturing a semiconductor device according to claim 3, wherein
a recess that is recessed upward is formed in the inner surface of the upper die, and
a tip end portion of the ring portion located in a direction extending from the frame body toward the ring portion via the connecting portion extends to the recess so as not to be in contact with the inner surface of the upper die.

5. The method for manufacturing a semiconductor device according to claim 1, wherein
a stepped portion is formed in the pin, and
the ring portion is sandwiched between the upper die and the stepped portion of the pin, to be fixed.

6. The method for manufacturing a semiconductor device according to claim 1, wherein
a recess that is recessed upward is formed in the inner surface of the upper die,
the connecting portion is bent downward, and
a tip end portion of the ring portion located in a direction extending from the frame body toward the ring portion via the connecting portion extends to the recess so as not to be in contact with the upper die and the lower die, and is bent upward.
